(19) United States
(12) Patent Application Publication
(10) Pub. No.: US 2019/0393561 A1
(43) Pub. Date: Dec. 26, 2019

(54) CUSTOMIZED BMS MODULE AND DESIGN METHOD THEREFOR

(71) Applicant: LG CHEM, LTD., Seoul (KR)

(72) Inventors: Dong Wan KO, Daejeon (KR); Ki Young LEE, Daejeon (KR)

(73) Assignee: LG CHEM, LTD., Seoul (KR)

(21) Appl. No.: 16/489,250

(22) PCT Filed: Aug. 9, 2018
(86) PCT No.: PCT/KR2018/009067

§ 371 Date: Aug. 27, 2019

(30) Foreign Application Priority Data
Aug. 18, 2017 (KR) 10-2017-0104786

(51) Int. Cl. H01M 10/42; G01R 31/3842; H05K 13/04; H05K 1/18

(52) U.S. Cl. CPC H01M 10/425; G01R 31/3842; H01M 2010/4271; H05K 1/189; H05K 13/04

(57) ABSTRACT

A customized battery management system (BMS) module, in which the BMS is separated into parts based on a function and is designed in advance, and a BMS part is selected and is mounted on a substrate so as to correspond to a separate BMS design request, without differently designing the BMS in accordance with different component specifications each time.

### TECHNICAL FIELD

This application claims priority to and the benefit of Korean Patent Application No. 10-2017-0104786 filed in the Korean Intellectual Property Office on Aug. 18, 2017, the entire contents of which are incorporated herein by reference.

The present invention relates to a customized battery management system (BMS) module and a design method therefor, and more particularly, to a customized BMS module, in which a BMS is separated into parts based on a function and is designed in advance, and a BMS part is selected and is mounted on a substrate so as to correspond to a separate BMS design request, without differently designing the BMS in accordance with different component specifications every time, so that it is possible to achieve standardization of the component and to decrease prime cost, verification cost consumed due to a development of a new circuit, and a development time, and a design method therefor.

### BACKGROUND ART

In general, a battery, that is, a secondary battery, used in an electric vehicle (EV), a hybrid vehicle (HV), and for family use or an industry use has high easiness of application according to a product group and has an electric characteristic, such as high energy density, and the like.

The secondary battery attracts attention as a new energy source for improving environment-friendly and energy efficiency in that it is possible to innovatively decrease use of fossil energy, which is the primary advantage, and a by-product according to the use of energy is not generated at all.

In this case, when each of the plurality of secondary batteries is alternately charged and discharged, it is necessary to manage the plurality of secondary batteries by efficiently controlling the charging/discharging so that the battery maintains an appropriate operation state and performance, and to this end, a state and performance of the battery are managed by using a battery management system (BMS), and the BMS serves to measure a current, a voltage, a temperature, and the like of the battery, estimate a state of charging (SOC) of the battery based on the measured current, voltage, temperature, and the like, and control an SOC so as to obtain best fuel consumption efficiency.

In the meantime, in the related art, a specification of a component required for each operation task is different, so that it is necessary to differently design the BMS every time when components and a circuit diagram are designed at the time of development of the BMS, which is an obstacle in achieving the standardization of the component, and is actually a reason causing problems, such as an increase in component cost, an increase in verification cost consumed due to a development of a new circuit, and an increase in development time.

In this respect, in order to solve various problems and limits generated in the BMS design and development process in the related art, the present inventors developed a customized BMS module, in which a BMS is separated into parts based on a function and is designed in advance, and a BMS part is selected and is mounted on a substrate so as to correspond to a separate BMS design request, without differently designing the BMS in accordance with different component specifications every time, so that it is possible to achieve standardization of the component and to decrease prime cost, verification cost consumed due to a development of a new circuit, and a development time, and a design method therefor.

### DETAILED DESCRIPTION OF THE INVENTION

### Technical Problem

The present invention is conceived to solve the foregoing problems, and provides a customized battery management system (BMS) module, in which a BMS is separated into parts based on a function and is designed in advance, and a BMS part is selected and is mounted on a substrate so as to correspond to a separate BMS design request, without differently designing the BMS in accordance with different component specifications every time, so that it is possible to achieve standardization of the component and to decrease prime cost, verification cost consumed due to a development of a new circuit, and a development time, and a design method therefor.

### Technical Solution

An exemplary embodiment of the present invention provides a customized battery management system (BMS) module, including: one or more BMS part modules, in which function-based circuits of a BMS are individually designed and reflected; and a substrate, on which the one or more BMS part modules are disposed and mounted, in which the one or more BMS part modules are selectively determined so as to correspond to a separate BMS design request and are disposed and mounted onto the substrate.

In the exemplary embodiment, circuits based on a power control function, a measurement function, a temperature sensing function, a booster function, and a DCDC converter function of the BMS may be individually designed and reflected to the one or more BMS part modules.

In the exemplary embodiment, one or more pins inserted into the substrate may be provided in each of the one or more BMS part modules.

In the exemplary embodiment, in the BMS design request, a list of selectable BMS part modules among the one or more BMS part modules may be pre-organized.

In the exemplary embodiment, the substrate may be a printed circuit board (PCB), a flexible PCB (FPCB), or a breadboard.

According to another exemplary embodiment of the present invention provides a method of designing a customized battery management system (BMS) module, the method including: individually designing and reflecting function-based circuits of a BMS to one or more BMS part modules; and selectively determining the one or more BMS part modules so as to correspond to a separate BMS design request and disposing and mounting the determined BMS part modules on a substrate.

### Advantageous Effects

According to one aspect of the present invention, a BMS is separated into parts based on a function and is designed in advance, and a BMS part is selected and is mounted on a substrate so as to correspond to a separate BMS design request, without differently designing the BMS in accordance with different component specifications every time, so that it is possible to achieve standardization of the component and to decrease prime cost, verification cost consumed due to a development of a new circuit, and a development time.

### BRIEF DESCRIPTION OF DRAWINGS

FIG. 1 is a diagram schematically illustrating a configuration of a customized battery management system (BMS) module 100 according to an exemplary embodiment of the present invention.

FIG. 2 is a diagram illustrating a state in which each of one or more BMS part modules 110 is selected according to different BMS design requests 1 and 2.

FIG. 3 is a flowchart illustrating a method of designing the customized BMS module 100 illustrated in FIG. 1 in order.

### BEST MODE

Hereinafter, an exemplary embodiment is presented for help understanding of the present invention. However, the exemplary embodiment below is simply provided for easier understanding of the present invention, and the contents of the present invention are not limited by the exemplary embodiment.

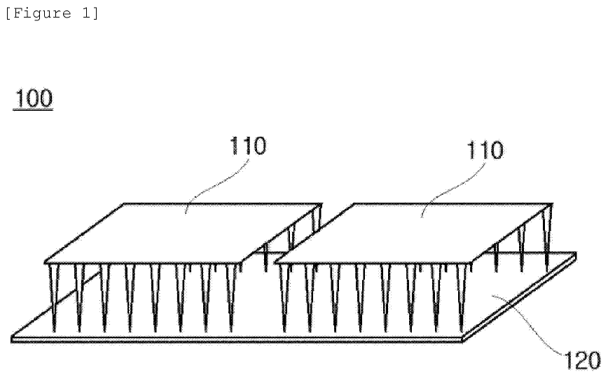

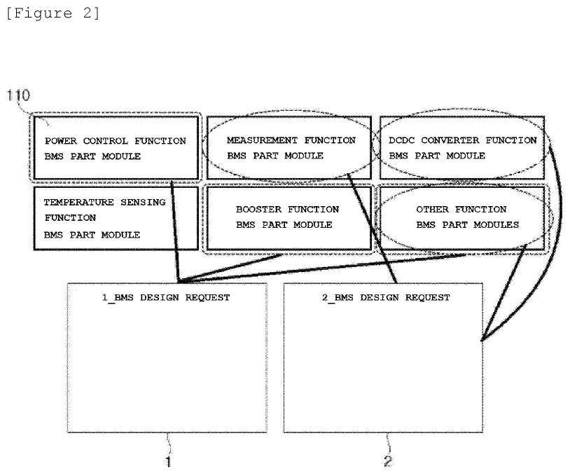

FIG. 1 is a diagram schematically illustrating a configuration of a customized battery management system (BMS) module 100 according to an exemplary embodiment of the present invention, and FIG. 2 is a diagram illustrating a state in which each of one or more BMS part modules 110 is selected according to different BMS design requests 1 and 2.

Referring to FIGS. 1 and 2, the customized BMS module 100 according to an exemplary embodiment of the present invention may generally include one or more BMS part modules 110 and a substrate 120.

First, the BMS part module 110 may mean a component (or an element), in which a function-based circuit of the BMS is individually designed and reflected, and for example, various functions, such as a power control function, a measurement function, a temperature sensing function, a booster function, and a DCDC converter function of the BMS, performed in the BMS are separately designed based on each function and are reflected to an element.

In this case, one or more pins, which are insertable into pattern recesses provided in the substrate 120, which is to be described below, are provided at one side (for example, a lower side) of the BMS part module 110, and according to the insertion of the pin into the pattern recess, the BMS part module 110 and the substrate 120 are electrically connected with each other and are electrically conducted.

In the meantime, in the BMS, various functions may be performed as described above, and the plurality of BMS part modules 110 is also formed so as to correspond to the various functions, and when the plurality of BMS part modules 110 may be designed first, and then may be selectively determined so as to correspond to a separate BMS design request, which will be described with reference to FIG. 2.

Referring to FIG. 2, the BMS performs various functions, such as a power control function, a measurement function, a temperature sensing function, a booster function, and a DCDC converter function, and it can be seen that the plurality of BMS part modules 110 is also designed so as to correspond to various functions.

Particularly, for the first BMS design request (for example, a component specification demanded by user A), the BMS part module corresponding to the power control function, the BMS part module corresponding to the booster function, and the BMS part modules performing other functions may be selected and determined, and for the second BMS design request (for example, a component specification demanded by user B), the BMS part module corresponding to the measurement function, the BMS part module corresponding to the DCDC converter function, and the BMS part modules performing other functions may be selected and determined.

That is, the different BMS part modules 110 may be selectively disposed and mounted on the different substrates 120, respectively, based on the BMS design request, so that it is possible to standardize a component, it is possible to save development time taken according to verification by a development of a new circuit, and it is not necessary to design a new BMS circuit every time which prevents an increase in cost.

Next, the substrate 120 means a region, in which the one or more BMS part modules 110 are disposed and mounted, and for example, a substrate, such as a printed circuit board (PCB), a flexible PCB (FPCB), or a breadboard, may be applied.

In this case, the patterned pattern recesses maybe formed at an upper side of the substrate 120, and the pins provided to the BMS part module 110 may be inserted into and mounted to the pattern recesses.

Particularly, the pattern recess of the substrate 120 does not have a specific form, but is simply arranged in a repeated pattern, so that the disposition position of the BMS part module 110 may be freely adjusted.

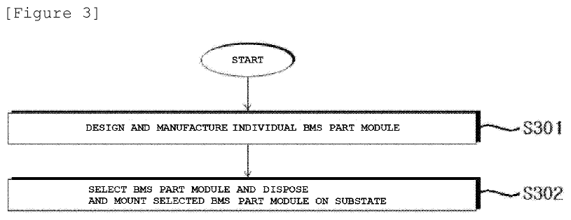

Next, a process of designing the customized BMS module 110 will be sequentially described with reference to FIG. 3.

FIG. 3 is a flowchart illustrating a method of designing the customized BMS module 100 illustrated in FIG. 1 in order.

Referring to FIG. 3, first, a function-based circuit of the BMS is individually designed and reflected to one or more BMS part modules 110 (S301). In this process, in order to correspond to various functions performed by the BMS, the plurality of BMS part modules 110 may be designed.

Next, one or more BMS part modules 110 are selectively determined so as to correspond to different BMS design requests and are disposed and mounted onto the substrates 120, respectively (S302). In this case, the pins provided in each BMS part module 110 are inserted to the upper side of the substrate 120, so that the BMS part module 110 and the substrate 120 are electrically connected and conducted.

As described above, according to the present invention, the function-based circuits of the BMS performing various functions are separated, and then are designed and reflected based on each element, and are selectively mounted according to different BMS design requests, so that it is possible to achieve standardization of a component without differently designing the BMS every time in accordance with different component specification, and it is possible to decrease prime cost, decrease verification cost consumed due to a development of a new circuit, and decrease development time.

In the forgoing, the present invention has been described with reference to the exemplary embodiment of the present invention, but those skilled in the art may appreciate that the present invention may be variously corrected and changed within the range without departing from the spirit and the area of the present invention described in the appending claims.

1. A customized battery management system (BMS) module, comprising:
one or more BMS part modules, in which function-based circuits of a BMS are individually designed and reflected; and
a substrate, on which the one or more BMS part modules are disposed and mounted,
wherein the one or more BMS part modules are selectively determined so as to correspond to a separate BMS design request and are disposed and mounted onto the substrate.

2. The customized BMS module of claim 1, wherein circuits based on a power control function, a measurement function, a temperature sensing function, a booster function, and a DC-DC converter function of the BMS are individually designed and reflected to the one or more BMS part modules.

3. The customized BMS module of claim 1, wherein one or more pins are inserted into the substrate and are provided in each of the one or more BMS part modules.

4. The customized BMS module of claim 1, wherein in the BMS design request, a list of selectable BMS part modules among the one or more BMS part modules is pre-organized.

5. The customized BMS module of claim 1, wherein the substrate is a printed circuit board (PCB), a flexible PCB (FPCB), or a breadboard.

6. A method of designing a customized battery management system (BMS) module, the method comprising:
individually designing and reflecting function-based circuits of a BMS to one or more BMS part modules; and
selectively determining the one or more BMS part modules so as to correspond to a separate BMS design request and disposing and mounting the determined one or more BMS part modules on a substrate.

7. The method of claim 6, wherein circuits based on a power control function, a measurement function, a temperature sensing function, a booster function, and a DC-DC converter function of the BMS are individually designed and reflected to the one or more BMS part modules.

8. The method of claim 6, wherein one or more pins inserted into the substrate are provided in each of the one or more BMS part modules.

9. The method of claim 6, wherein in the BMS design request, a list of selectable BMS part modules among the one or more BMS part modules is pre-organized.

10. The method of claim 6, wherein the substrate is a printed circuit board (PCB), a flexible PCB (FPCB), or a breadboard.
